(19) United States
(12) Patent Application Publication
(10) Pub. No.: US 2014/0030532 A1
(43) Pub. Date: Jan. 30, 2014

(54) METHOD OF FORMING METAL THIN FILM USING ELECTROLESS DEPOSITION AND THIN FILM DEVICE FABRICATED USING THE METHOD

(71) Applicant: KOREA INSTITUTE OF SCIENCE AND TECHNOLOGY, Seoul (KR)

(72) Inventors: Ji Young BYUN, Seoul (KR); Sang Hoon KIM, Gyeonggi-do (KR); Ju Yeon HWANG, Gyeonggi-do (KR); Heon Phil HA, Seoul (KR)

(73) Assignee: KOREA INSTITUTE OF SCIENCE AND TECHNOLOGY, Seoul (KR)

(21) Appl. No.: 13/663,728

(22) Filed: Oct. 30, 2012

(30) Foreign Application Priority Data
Jul. 26, 2012 (KR) 10-2012-0081953

(51) Int. Cl. H01B 19/04; C23C 16/503; B32B 15/00; C23C 16/48; B05D 5/10; B05D 1/36; C23C 16/44; C23C 16/50

(52) U.S. Cl. 428/457; 427/304; 427/123; 427/585; 427/569; 427/265; 427/207.1; 427/248.1; 427/305

(57) ABSTRACT

Provided is a technique for electroless deposition (ELD) for forming metal conductive layer on an insulating substrate made of glass, polymer, etc. According to an aspect, an adhesive layer and a catalyst layer are formed on a substrate using a dry deposition method, such as are plasma deposition (APD) or sputtering, etc., and electroless deposition is performed thereon, thereby forming a metal thin, film. Therefore, it is possible to significantly simplify a complicated pretreatment process required for electroless depositions and increase adhesive strength of a deposited metal thin film.

### CROSS-REFERENCE TO RELATED APPLICATION

This application claims priority to and the benefit of Korean Patent Application No. 2012-0081953, filed on Jul. 26, 2012, the disclosure of which is incorporated herein by reference in its entirety.

### BACKGROUND

1. Field of the Invention

The present invention relates to a method of forming a metal thin film using electroless deposition and a thin film device fabricated using the method, and more particularly, to a method of forming a metal thin film using electroless deposition through dry pretreatment, such as arc plasma deposition (APD), sputtering, or the like, and an electronic device fabricated using the method.

2. Discussion of Related Art

Since an insulator cannot transmit electric charges, it is difficult to electrolytically deposit arbitrary materials on such an insulator. Therefore, electroless deposition which is a reduction reaction without using electrical energy, is used. A driving force for reducing metal ions is provided by a reducing agent in a solution. For example, when formaldehyde (HCHO) is used as a reducing agent for copper deposition, the following chemical reaction occurs:

Cu²+2HCHO+4OH⁻=CuO+2HCOO⁻+H₂+2H₂O

A catalyst provides a temporary electron bridge between metal ions and a reducing agent to lower activation energy required for depositing a metal, thereby facilitating a reaction. Therefore, electroless deposition is performed after a palladium (Pd) catalyst layer for activating a reaction of a reducing agent is deposited on a substrate. A conventional electroless deposition technique requires complicated pretreatment for forming such a Pd catalyst layer. In detail, a substrate is cleaned and etched, sensitized with a mixture solution of SnCl₂ and HCl, and then activated with a mixture solution of PdCl₂ and HCl. Cleaning with water is inserted between the respective operations. Pd is activated by the following reaction;

Pd²⁺+Sn^{2+→}PdO⁺+Sn⁴⁺

Electroless deposition starts at each PdO location.

Recently, the processing has been simplified by activating Pd with a solution of SnCl₂/PdCl₂/HCL, and accelerating it with HCl. That is, a colloid having cores of a Sn/Pd alloy is created by a SnCl₂ protection layer, and Sn is removed from the colloid using a HCl solution to thereby make Pd locations at which electroless deposition (ELD) will start.

Meanwhile, there is a method of directly depositing a copper thin film without using plating. However, since copper has weak adhesive strength with respect to most materials, a layer capable of improving adhesive strength needs to be formed between a substrate and a copper layer. However, it is also difficult to properly perform copper deposition on a material used to improve adhesive strength.

For example, a deposition bath containing CuSO₄ and H₂SO₄ prevents a copper layer from being properly adhered due to fast oxidation upon deposition. Also, a copper deposition bath increases pH since it contains base components, such as lithium (Li), sodium (Na), and potassium (K), which increases the reaction rate of deposition. Furthermore, it is not preferable to use a large amount of base components upon fabricating a substrate. Use reason is that the remaining base metal ions may move under the electric field of an interface such as dioxide in a substrate to carry positive ion charges to undesired regions changing the characteristics of devices.

Electroless deposition requires complicated pretreatment of a substrate, and a conventional wet method using an aqueous solution requires complicated processing and causes environmental problems due to waste fluid.

### PRIOR ART REFERENCES

Korean Published Patent No. 10-2004-0015090

Korean Published Patent No. 10-2004-0004556

### SUMMARY OF THE INVENTION

The present invention is directed to a technique for simplifying a pretreatment process for electroless deposition and improving adhesive strength of an electroless-deposited metal thin film by forming a catalyst layer using a dry deposition method, such as arc plasma deposition (APD) or sputtering, upon electroless deposition.

The present invention is also directed to an environmentally-friendly electroless deposition method that does not discharge waste fluid since it uses a dry process.

The present invention is also directed to an electroless deposition method capable of forming a fine circuit pattern by depositing a patterned adhesive layer and a patterned catalyst layer in a dry pretreatment process.

The present invention is also directed to a technique for providing flexible electronic devices or transparent, soft electrodes by forming a thin film on a polymer substrate, an insulating, transparent, flexible substrate as well as on a glass substrate.

According to an aspect of the present invention, there is provided a method of forming a metal thin film using electroless deposition, including: preparing a substrate; forming a catalyst layer on the substrate using a dry deposition method; and forming a metal thin film on the catalyst layer using electroless deposition.

The substrate may be an electrical insulator.

The substrate may be made of glass, flexible polymer, or elastic polymer.

The substrate may be made of at least one material selected from a group consisting of glass, epoxy, phenolic resin, polyimide, polyester, glass epoxy, silicone rubber, polydimethylsiloxane (PDMS), and polyvinylidene difluoride (PVDF).

The dry deposition method may include at least one method selected from a group consisting of thermal evaporation, e-beam evaporation, plasma assisted chemical vapor deposition, and sputtering.

The dry deposition method may include arc plasma deposition.

The catalyst, layer may be formed of at least one material selected from a group consisting of palladium (Pd), platinum (Pt), silver (Ag), and their alloys,

The catalyst layer may be formed into a specific pattern using a mask, and the electroless deposition may be performed along the specific pattern, thereby forming the metal thin film.

The method may further include, after the preparing of the substrate and before the forming of the catalyst layer, forming an adhesive layer on the substrate.

The forming of the adhesive layer may be performed by a dry deposition method.

The dry deposition method used in the forming of the adhesive layer may be the same dry deposition method as that used for forming the catalyst layer,

The adhesive layer and the catalyst layer may be formed into a specific pattern using a mask, and the electroless deposition may be performed along the specific pattern.

The adhesive layer may be made of at least one material selected from a group consisting of titanium (Ti), molybdenum (Mo), nickel (Ni) chromium (Cr), aluminum (Al), silver (Ag), and their alloys.

The adhesive layer may be made of a NiCr alloy, titanium (Ti), or molybdenum (Mo).

The electroless deposition may be performed using a reducing agent including at least one material selected from a group consisting of formaldehyde (HCHO), glyoxylic acid produced based on glycerine, sodium hypophosphite (NaPO₂H₂.H₂O), a borobydride solution, and dimethylamine-borane (DMAB).

The metal thin film may be formed of at least one material selected from a group consisting of copper (Cu), nickel (Ni), gold (An), silver (Ag), and their alloys.

According to another embodiment of the present invention, there is provided a thin film device including the metal thin film formed according to the method described above.

Therefore, by forming a catalyst layer using a dry deposition method, such as arc plasma deposition (API)) or sputtering, etc. on substrate, it is possible to simplify a pretreatment process for electroless deposition and improve adhesive strength of an electroless-deposited metal thin film.

Also, since the pretreatment process is a dry process, no waste fluid is discharged.

Furthermore, by depositing a patterned adhesive layer and a patterned catalyst layer in the pretreatment process, a fine circuit pattern can be formed.

In addition, since a thin film can be formed on a polymer substrate, an insulating, transparent, flexible substrate, etc., as well as on a glass substrate, flexible electronic devices or transparent, soft electrodes can be fabricated.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 is a flowchart illustrating a method of forming a metal thin film using electroless deposition, according to an embodiment of the present invention;

FIG. 2 is a picture of the cross section of a copper thin film formed according to an inventive example 1, wherein the picture was taken by a scanning electron microscope (SEM);

FIG. 3 is a graph showing changes in thickness of the copper thin film formed according to the inventive example 1 with respect to a deposition time;

FIG. 4 is a graph showing changes in thickness of a copper thin film formed according to an inventive example 2 with respect to a deposition time;

FIG. 5 is a picture of the cross section of a copper thin film formed according to an inventive example 3, wherein the picture was taken by a SEM; and

FIG. 6 is a picture of a copper thin film formed according to an inventive example 4.

### DETAILED DESCRIPTION OF EXEMPLARY EMBODIMENTS

Exemplary embodiments of the present invention will be described in detail below with reference to the accompanying drawings. While the present invention is shown and described in connection with exemplary embodiments thereof, it will be apparent to those skilled in the art that various modifications can be made without departing from the spirit and scope of the invention. Accordingly, the shapes, sizes, etc., of some of elements shown in the drawings may be exaggerated for clarity, and like numbers refer to like elements throughout the description of the figures.

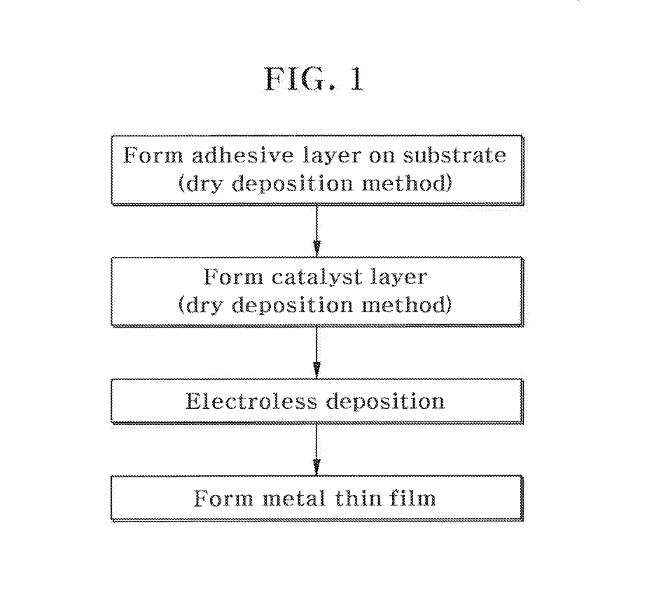

FIG. 1 is a flowchart illustrating a method of forming a metal thin film using an electroless deposition, according to an embodiment of the present invention.

Referring to FIG. 1, the method of forming the metal thin film using the electroless deposition may include: preparing a substrate; forming a catalyst layer on the substrate using a dry deposition method; and forming a metal thin film on the catalyst layer using electroless deposition.

First, a substrate is prepared.

The substrate is cleaned to remove foreign materials from the substrate. The substrate may be an electrical insulator. If the substrate is a conductor, electro-deposition can be performed on the substrate, however, if the substrate is an insulator, electro-deposition is impossible, and accordingly, in this case, electroless deposition using the chemical reduction of a metal is performed.

The substrate may be a rigid substrate, such as a glass substrate, a rigid PCB substrate, or the like. The glass substrate may be made of glass for display such as LCD, etc., and the rigid PCB substrate may be a general PCB substrate for main board, made of epoxy or phenolic resin, etc. Then, electroless deposition is performed on the glass substrate or the rigid PCB substrate to form wirings, electrodes, etc.

The substrate may contain a flexible or elastic polymer material. In detail, the substrate may be made of at least one material selected from a group consisting of epoxy resin, polyimide resin, polyester resin, glass epoxy resin, silicone rubber, polydimethylsiloxane (PDMS), and polyvinylidene difluoride (PVDF). Specifically, if the substrate is made of a flexible or elastic polymer material, the substrate may be effectively applied to bendable electronic devices.

The substrate may be used as a PCB substrate for main board, a flexible PCB (fPCB) substrate for a connector of an. LCD or a portable electronic device, such as a mobile phone, a camera, etc., or an IC substrate for semiconductor package. The PCB substrate or the IC substrate is based on epoxy or phenolic resin, and the fPCB substrate may be based on polyimide, polyester (PET), or glass epoxy.

Then, an adhesive layer may be formed on the substrate.

The adhesive layer may be selectively formed. That is, if the adhesive strength between the substrate and a catalyst layer is sufficiently strong so that stability can be ensured, no adhesive layer needs to be formed, whereas if stability cannot be ensured due to weak adhesive strength between the substrate and the catalyst layer, an adhesive layer is formed between the substrate and the catalyst layer in order to improve adhesive strength between the substrate and the catalyst layer.

The adhesive layer may be formed by a dry deposition method. The same dry deposition method can be used to form a catalyst layer. In this case, successive processing is possible, resulting in process simplification.

The adhesive layer may be formed into a specific pattern using a mask. In the following process, the catalyst layer will he formed in correspondence to the pattern of the adhesive layer, and electroless deposition will also be performed along the pattern of the adhesive layer. As a result, a metal thin film can be formed in correspondence to the pattern of the adhesive layer, the metal thin film can be used to form the wirings of a PCB substrate, etc., and the metal thin film can also be used as various transparent, flexible electrode elements.

The adhesive layer may be formed of at least one material selected from a group consisting of titanium (Ti), molybdenum (Mo), nickel (Ni), chromium (Cr), aluminum (Al), silver (Ag), and their alloys. Preferably, the adhesive layer may be formed of a NiCr alloy, Ti, or Mo, wherein the NiCr alloy may have a Ni:Cr ratio of 80:20.

Then, a catalyst layer may be formed by a dry deposition method.

The dry deposition method may mean deposition without using a wet process. The dry deposition method may include at least one method selected from a group consisting of thermal evaporation, e-beam evaporation, plasma assisted chemical vapor deposition, and sputtering. Specifically, the dry deposition method may include arc plasma deposition (APD). The plasma assisted chemical vapor deposition, which is a kind of chemical vapor method, is performed by blowing a vaporized reagent into a chamber, and forming an RF plasma in the chamber to cause a reaction at a low temperature, thereby depositing a desired material on a substrate. The thermal evaporation is performed by heating a target metal and depositing metal atoms emitted from the metal by thermal energy directly onto a substrate. The e-beam evaporation is performed by hitting a target metal with an e-beam having high energy, and depositing metal atoms emitted from the metal directly onto a substrate. The APD is performed by producing arc using a dry method, instead of a wet method, to make a target metal into plasma and depositing the metal plasma directly onto a substrate. The sputtering is performed by hitting a target metal with argon (Ar) ions, etc. having high energy and depositing metal atoms emitted from the metal directly onto a substrate.

According to this embodiment, by adopting a dry deposition method which is a dry process, instead of a wet process, it is possible to omit many processes required for the wet process, which leads to process simplification. Also, since the dry deposition method makes no waste fluid, etc., it is environmentally-friendly. Also, due to process simplification, quality management is easy, and the amount of deposited catalyst can be reduced compared to the wet process, which leads to a reduction of the use amount of catalyst which is a precious metal.

The catalyst layer is formed on the substrate to facilitate the reduction reaction of metal ions existing in an electroless deposition solution, thereby ensuing high speed of electroless deposition. The catalyst layer may be formed of a noble metal, etc. For example, the catalyst layer may be formed of at least one material selected from a group consisting of palladium (Pd), platinum (Pt), silver (Ag), and their alloys.

If the adhesive layer is formed into a specific pattern, the catalyst layer may also be formed into a specific pattern corresponding to the pattern of the adhesive layer, using a mask. Metal ions existing in the electroless deposition solution are reduced along the specific pattern of the catalyst layer, thereby forming a deposition layer. As a result, a metal thin film may be formed along the pattern of the catalyst layer. The metal thin film may be used to form the wirings of a PCB substrate, etc. and also used as various transparent, flexible electrode elements.

Then, a metal thin film may be formed on the catalyst layer using electroless deposition.

By the electroless deposition, metal ions existing in the electroless deposition solution are deposited as a metal on the substrate by a reducing agent so that a deposition layer is formed on the substrate. Since the reduction of the metal is accelerated by a catalyst, reduction of the metal may occur more actively on the catalyst layer. The reducing agent may include at least one material selected from a group consisting of formaldehyde (HCHO), glyoxylic acid produced based on glycerine, sodium hypophosphite (NaPO₂H₂.H₂O), a borobydride solution, and dimethylamine-borane (DMAB). However, since HCHO vapor is harmful, glyoxylic acid may be preferably used as a reducing agent.

The metal thin film may be formed of an arbitrary metal having excellent conductivity. For example, the metal thin film may be formed of at least one material selected from a group consisting of copper (Cu), nickel (Ni), aurum (Au), silver (Ag), and their alloys. The metal thin film may be formed of a metal that is appropriate for the purpose of a substrate onto which the metal thin film is deposited. Specifically, if the metal thin film is deposited on a PCB substrate, the metal thin film may be formed of Cu.

If the adhesive layer and the catalyst layer are formed into a specific pattern using a mask, the electroless deposition may also be performed along the pattern of the adhesive layer and the catalyst layer, so that the metal thin film may also be formed in the shape of the specific pattern. The metal thin film may be used to form the wirings of a PCB substrate, and used as various transparent, flexible electrode elements.

According to another embodiment of the present invention, there is provided a thin film device including the metal thin film formed according to the method described above.

The thin film device may include a seed layer of copper wirings for a connector for connecting a main board for an LCD to a driving IC, a seed layer of copper wirings for a connector in a portable electronic device (a mobile phone, a camera, etc.), a seed layer of main board copper wirings used in a general electronic device, a seed layer of copper wirings for an IC package, and the like.

Hereinafter, inventive examples of the present invention and comparative examples will be described in detail.

### INVENTIVE EXAMPLE 1

Forming a Copper Thin Film on a Glass Substrate

A copper thin film was formed on a glass substrate using the following method:

First, the glass substrate was put into a piranha solution for 30 minutes, wherein the piranha solution was prepared by mixing H₂SO₄ with H₂O₂ at a volume ratio of 3:1 (H₂SO₄:H₂O₂), in order to remove foreign materials from the surface of the glass substrate, and then, the glass substrate was cleaned with acetone, ethyl alcohol, and distilled water, in this order, wherein cleaning with each material was done for 15 minutes.

The cleaned glass substrate was dried with N₂ gas.

Next, Ti was deposited on the glass substrate using arc plasma deposition under a condition of 1080 μF, 200V, 3 Hz, and 200 pulses, thereby forming an adhesive layer.

Successively, Pd was deposited on the adhesive layer using arc plasma deposition under a condition of 1080 μF, 100V, 3 Hz, and 200 pulses, thereby forming a catalyst layer.

Thereafter, a copper thin film was formed by performing electroless deposition using an electroless deposition solution. The electroless deposition solution is a typical electroless deposition solution that has been widely used in the art. That is, the copper deposition solution was prepared by mixing CuSO₄.5H₂O of 5 g/L, KNaC₄H₄O₆.4H₂O of 25 g/L, sodium hydroxide of 10 g/L, and formalin (37 wt % in a HCHO aqueous solution).

The copper deposition solution was stirred at a speed of 400 rpm at 22° C., and the glass substrate on which the adhesive layer and the catalyst layer had been deposited was put in the copper deposition solution, for 5 minutes, 10 minutes, 30 minutes, 1 hour, and 2 hours, so that electroless deposition was performed.

After the electroless deposition was completed, the deposition solution remaining on the surface of the substrate was washed out with distilled water, and the resultant substrate was dried with N₂ gas.

Evaluation of the Properties of the Copper Thin Film

Evaluation of the properties of the copper thin film formed by the method described above was performed as follows:

Observation of the Deposition Layer

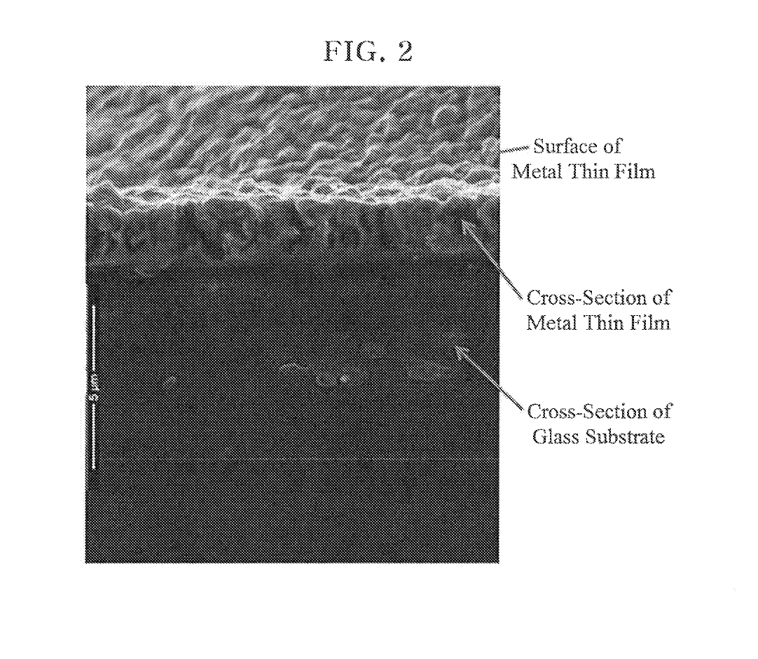

The surface and cross-section of the copper thin film were observed using a scanning electron microscope (SEM). The results of the observation are shown in FIG. 2. It Is seen from FIG. 2 that the copper thin film was densely formed on the substrate.

Thickness of the Copper Thin Film

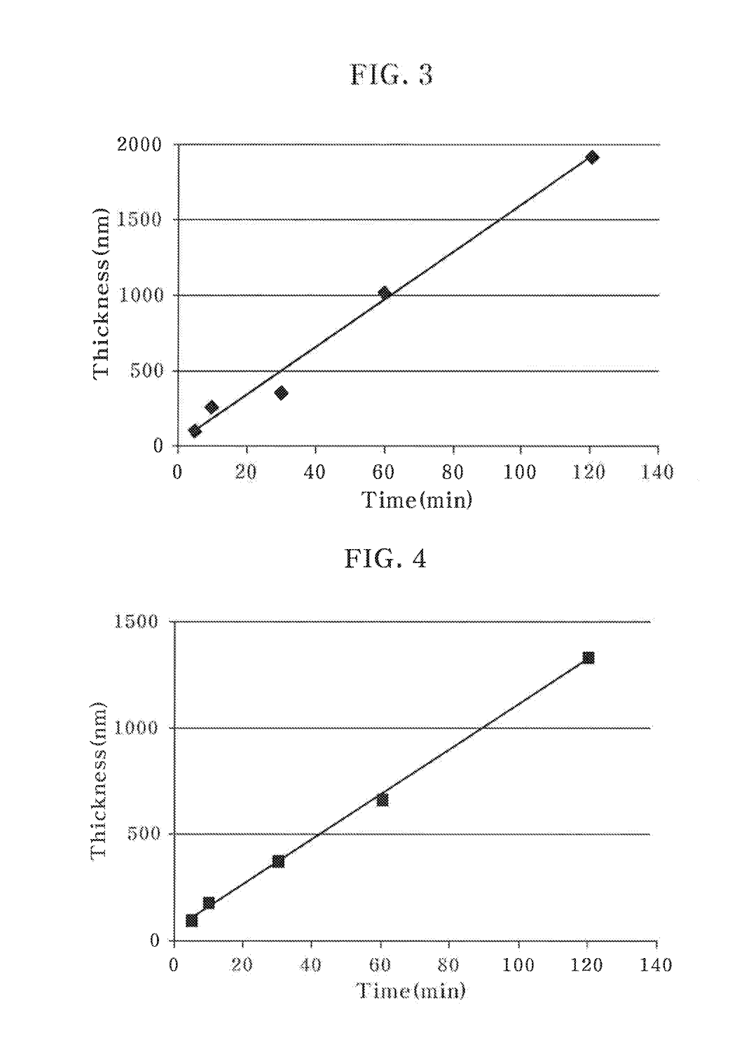

The thickness of the copper thin film according to a deposition time was observed, and the results of the observation are shown in FIG. 3. It is seen from FIG. 3 that the thickness of the copper thin film was nearly linearly proportional to the deposition time until the thickness of the copper thin film reached 2 μm. Accordingly, it will be understood that the thickness of the copper thin film can be finely adjusted if the thickness of the copper thin film is less than 2 μm.

Electrical Properties

The electrical properties of the copper thin film were evaluated by measuring the sheet resistance of the copper thin film using a 4-point probe, and the results of the evaluation are shown in Table 1 below.

TABLE 1

| | | 10 | | | |
|---|---|---|---|---|---|
| | 5 minutes | minutes | 30 minutes | 1 hour | 2 hours |
| Sheet | 3.1 × 10⁻¹ | 9.7 × 10⁻² | 3.9 × 10⁻² | 2.6 × 10⁻² | 1.2 × 10⁻² |
| resistance | | | | | |
| (Ohm/□) | | | | | |

Referring to Table 1, it is seen that as the thickness of the deposited copper thin film increases, sheet resistance is reduced. The reason is because conductivity was improved due to an increase in thickness of the copper layer.

Adhesive Strength Property

Also, adhesive strength was tested to ensure whether deposition was stably performed. As a method for testing the adhesive strength of the copper thin film, ASTM D-3359 was used. According to the ASTM D-3359, the adhesive strength of the copper thin film was evaluated by attaching an adhesive tape on the copper thin film, then detaching the adhesive tape from the copper thin film, and classifying the copper thin film into one of levels 1 to 5 according to the percentage of the removed portion with respect to the entire copper thin film. A case where no portion of the copper thin film was removed is classified as level 5, a case where 5% or less of the copper thin film was removed is classified as level 4, a case where 5 to 15% of the copper thin film was removed is classified as level 3, a case where 15 to 35% of the copper thin film was removed is classified as level 2, a case where 35 to 65% of the copper thin film was removed is classified as level 1, and a case where 65% or more of the copper thin film was removed is classified as level 0.

The adhesive strength test was performed on the copper thin films that were deposited for 15 minutes and for 30 minutes. The copper thin film, deposited for 15 minutes was classified as level 5, and the copper thin film deposited for 30 minutes was classified as level 3. The results show that the adhesive strength of each copper thin film is similar to that of a copper thin film deposited using conventional electroless deposition (referring to M. Charbonier et al., Surf. Coat. Technol. 200, 5478-5486 (2006)), in the case of conventional electroless deposition, a copper thin film deposited for 15 minutes was classified as level 5, and a copper thin film deposited for 30 minutes could not be classified into a constant level.

It will be understood from the above results that when a pretreatment process of electroless deposition is performed by a dry process instead of a wet process, the pretreatment process of the electroless deposition can be simplified without deteriorating the physical properties of a metal thin film, and also environmental pollution does not occur.

### INVENTIVE EXAMPLE 2

Forming a Copper Thin Film on a Glass Substrate

A copper thin film was formed by the same method as that used in the inventive example 1 except that the adhesive layer formed on the glass substrate was made of molybdenum (Mo).

Evaluation on the Properties of the Copper Thin Film

The properties of the copper thin film were evaluated according to the same evaluation method and criteria as those used in the inventive example 1.

Thickness of the Copper Thin Film

The thickness of the copper thin film according to a deposition time was observed, and the results of the observation are shown in FIG. 4. It is seen from FIG. 4 that the thickness of the copper thin film was nearly linearly proportional to the deposition time until the thickness of the copper thin film reached 1.5 μm. Accordingly, it will be understood that the thickness of the copper thin film can be finely adjusted If the thickness of the copper thin film is less than 1.5 μm.

Electrical Properties

The electrical properties of the copper thin film were evaluated by measuring the sheet resistance of the copper thin film using a 4-point probe, and the results of the evaluation are shown in Table 2 below.

TABLE 2

| | | 10 | | | |
|---|---|---|---|---|---|
| | 5 minutes | minutes | 30 minutes | 1 hour | 2 hours |
| Sheet | 5.9 × 10⁻¹ | 2.2 × 10⁻¹ | 7.6 × 10⁻² | 3.9 × 10⁻² | 2.2 × 10⁻² |
| resistance | | | | | |
| (Ohm/□) | | | | | |

Referring to Table 2, it is seen that as the thickness of the deposited copper thin film increases, sheet resistance is reduced. The reason is because conductivity was improved due to an increase in thickness of the copper layer.

Adhesive Strength Property

The adhesive strength of the copper thin film was tested according to the same method and criteria as those used in the inventive example 1.

The adhesive strength test was performed on the copper thin films that were deposited for 15 minutes and for 30 minutes. The copper thin film deposited for 15 minutes was classified as level 5, and the copper thin film deposited for 30 minutes was classified as level 4. The results show that the adhesive strength of each copper thin film is similar to or better than that of a copper thin film deposited using conventional electroless deposition

### INVENTIVE EXAMPLE 3

Forming a Copper Thin Film on a polymer Substrate

A copper thin film was formed by the same method as that used in the inventive example 1 except that a substrate made of polyimide which is a bendable polymer substance was used, and the adhesive layer was formed of a NiCr (80:20) alloy. The polyimide substrate was ultrasonically cleaned with ethyl alcohol and distilled water, in this order, wherein cleaning with each material was done for 15 minutes. Then, the substrate was dried with N₂ gas.

Evaluation on the Properties of the Copper Thin Film

The properties of the copper thin film were evaluated according to the same evaluation method and criteria as those used in the inventive example 1.

Observation of the Deposition Layer

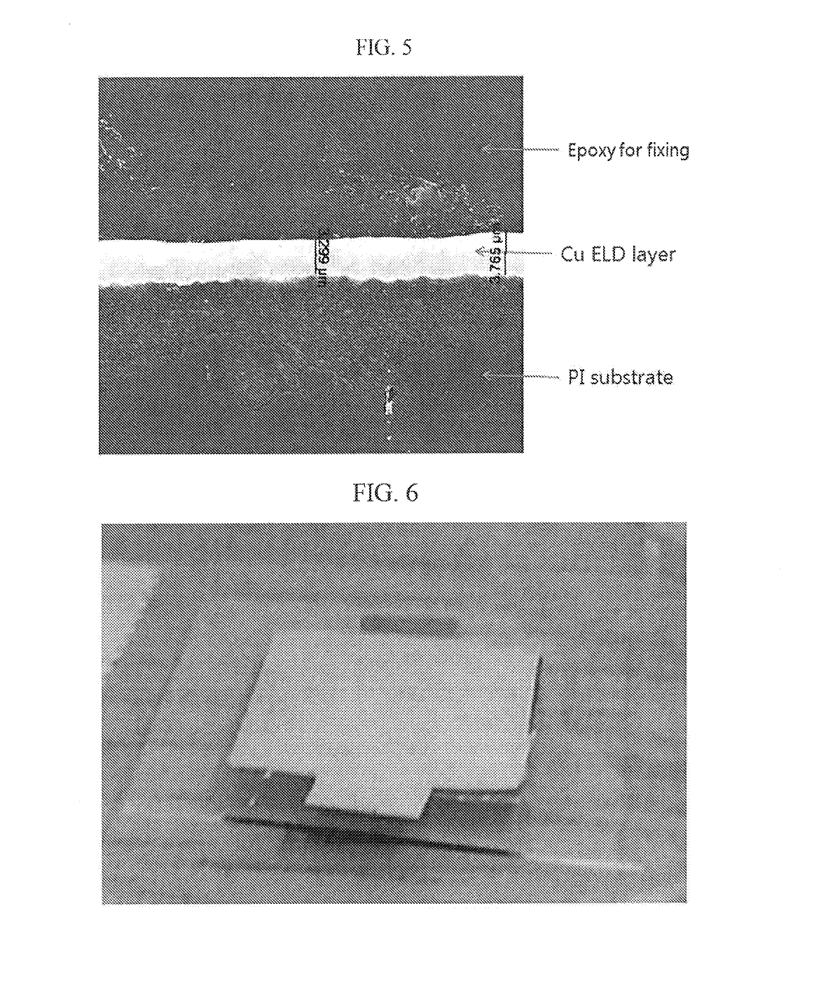

FIG. 5 is a picture of the cross section of the copper thin film formed according to the inventive example 3, wherein the picture was taken by a SEM. In order to photograph the cross section of the copper thin film with the SEM, epoxy was applied on the copper thin film and hardened. Referring to FIG. 5, it is seen that the copper thin film was densely formed with a thickness of about 3 um on a substrate.

Adhesive Strength Property

The adhesive strength test was performed on the copper thin films that were deposited for 15 minutes and for 30 minutes. The copper thin film deposited for 15 minutes was classified as level 5, and the copper thin film deposited for 30 minutes also was classified as level 5. The results show that the adhesive strength of each copper thin film is similar to that of a copper thin film deposited using conventional electroless deposition

### INVENTIVE EXAMPLE 4

Forming a Copper Thin Film on a Silicone Substrate

A copper thin film was formed by the same method as that used in the inventive example 1 except that a substrate made of silicone which is an elastic polymer substance was used, and the adhesive layer was formed of a NiCr (80:20) alloy. The silicone substrate was cleaned with ethyl alcohol and distilled water, in this order, wherein cleaning with each material was done for 15 minutes. Then, the substrate was dried with N₂ gas.

Evaluation on the Properties of the Copper Thin Film

The properties of the copper thin film were evaluated according to the same evaluation method and criteria as those used in the inventive example 1.

Observation of Deposition Layer

FIG. 6 is a picture of a copper thin film deposited on a transparent silicon substrate. Referring to FIG. 6, it is seen with the naked eye that the copper thin film was formed on the center portion of the transparent silicon substrate.

Adhesive Strength Property

The adhesive strength test was performed on the copper thin films that were deposited for 15 minutes and for 30 minutes. The copper thin film deposited for 15 minutes was classified as level 5, and the copper thin film deposited for 30 minutes also was classified as level 3. The results show that the adhesive strength of each copper thin film is similar to or better than that of a copper thin film deposited using conventional electroless deposition

The terminology used herein to describe embodiments of the invention is not intended to limit the scope of the invention. The articles “a,” “an,” and “the” are singular in that they have a single referent, however the use of the singular form in the present document should not preclude the presence of more than one referent. In other words, elements of the invention referred to in the singular may number one or more, unless the context clearly indicates otherwise. It will be further understood that the terms “comprises, ” “comprising, ” “includes, ” and/or “including,” when used herein, specify the presence of stated feature, items, steps, operations, elements, and/or components, but do not preclude the presence or addition of one or more other features, items, steps, operations, elements, components, and/or groups thereof.

It will be apparent to those skilled in the art that various modifications can be made to the above-described exemplary embodiments of the present invention without departing from the spirit or scope of the invention. Thus, it is intended that the present invention covers all such modifications provided they come within the scope of the appended claims and their equivalents.

What is claimed is:

1. A method of forming a metal thin film using electroless deposition, comprising;
preparing a substrate;
forming a catalyst layer on the substrate using a dry deposition method; and
forming a metal thin film on the catalyst layer using electrons deposition.

2. The method of claim 1, wherein the substrate is an electrical insulator.

3. The method of claim 1, wherein the substrate is made of glass, flexible polymer, or elastic, polymer.

4. The method of claim 1, wherein the substrate is made of at least one material selected from a group consisting of glass, epoxy, phenolic resin, polyimide, polyester, glass epoxy, silicone rubber, polydimethylsiloxane (PDMS), and polyvinylidene difluoride (PVDF).

5. The method of claim 1, wherein tire dry deposition method includes at least one method selected front a group consisting of thermal evaporation, e-beam evaporation, plasma assisted chemical vapor deposition, and sputtering.

6. The method of claim 1, wherein the dry deposition method includes are plasma deposition.

7. The method of claim 1, wherein the catalyst layer is formed of at least one material selected from a group consisting of palladium (Pd), platinum (Pt), silver (Ag), and their alloys.

8. The method of claim 1, wherein the catalyst layer is formed info a specific pattern using a mask, and electroless deposition is performed along the specific pattern, thereby forming the metal thin film.

9. The method of claim 1, further comprising, after the preparing of the substrate and before the forming of the catalyst layer, forming an adhesive layer on the substrate.

10. The method of claim 9, wherein the forming of the adhesive layer is performed by a dry deposition method.

11. The method of claim 9, wherein the dry deposition method used in the forming of the adhesive layer is the same dry deposition method as that used for forming the catalyst layer.

12. The method of claim 9, wherein the adhesive layer and the catalyst layer are formed into a specific pattern using a mask, and electroless deposition is performed along the specific pattern.

13. The method of claim 9, wherein the adhesive layer is made of at least one material selected from a group consisting of titanium (Ti), molybdenum (Mo), nickel (Ni), chromium (Cr), aluminum (Al), silver (Ag), and their alloys.

14. The method of claim 9, wherein the adhesive layer is made of a NiCr alloy, titanium (Ti), or molybdenum (Mo).

15. The method of claim 1, wherein the electroless deposition is performed using a reducing, agent including at least one material selected from a group consisting of formaldehyde (HCHO), glyoxylic acid produced based on glycerine, sodium hypophosphite (NaPO₂H₂.H₂O), a borobydride solution, and dimethylamine-borane (DMAB).

16. The method of claim 1, wherein the metal thin film is formed of at least one material selected from a group consisting of copper (Cu), nickel (Ni), gold (Au), silver (Ag), and their alloys.

17. A thin film device comprising the metal thin film produced by the method of claim 1.
